(19) United States
(12) Patent Application Publication
(10) Pub. No.: US 2015/0198988 A1
(43) Pub. Date: Jul. 16, 2015

(54) CORE SPECIFIC PROCESS VOLTAGE SCALING FOR OPTIMIZING MULTI-CORE OPERATION

(71) Applicant: QUALCOMM Incorporated, San Diego, CA (US)

(72) Inventors: Sachin Dileep DASNURKAR, San Diego, CA (US); Krishna Reddy DUSETY, San Diego, CA (US); Prasad Rajeevalochanam BHADRI, San Diego, CA (US)

(21) Appl. No.: 14/447,547

(22) Filed: Jul. 30, 2014

Related U.S. Application Data
(60) Provisional application No. 61/928,126, filed on Jan. 16, 2014.

(51) Int. Cl. G06F 1/26; G01R 19/12; G01R 31/28; G01R 19/00

(52) U.S. Cl. CPC G06F 1/26; G01R 19/0084; G01R 19/003; G01R 19/12; G01R 31/2834

(57) ABSTRACT

A multi-core processor comprising a plurality of cores, a plurality of core caches, each core cache associated with a single core, a plurality of low drop out (LDO) devices, each LDO device associated with a single core for scaling operating voltage to the core; and a memory for storing a lookup table that maps core operating frequency to core operating voltage, and a voltage scaling algorithm for determining a core specific voltage scaling factor for each cor. Each of the plurality of LDO devices applies the core specific voltage scaling factor determined by the algorithm. During operation, one core operates at a different operating voltage than a second core for the same operating frequency.

### CLAIM OF PRIORITY UNDER 35 U.S.C. §119

The present Application for Patent claims priority to Provisional Application No. 61/928,126, filed Jan. 16, 2014, and assigned to the assignee hereof and hereby expressly incorporated by reference herein.

### BACKGROUND

1. Field

The present disclosure relates generally to multi-core processors, and more particularly, to core specific voltage scaling of the processor.

2. Background

A multi-core processor uses a frequency/voltage table to set a common voltage for all cores within the processor based on the selected operating frequency for the currently running application/operation. A single voltage is selected based on the core having the worst case requirement, and that voltage is applied to all cores, regardless of whether one or more cores is capable of performing at a lower voltage for the particular operating frequency. This wastes power resources for the processor.

### SUMMARY

A method and apparatus for performing core specific voltage scaling of a multi-core processor is provided, which provides a customized voltage selection to each core. A multi-core processor has a plurality of cores, a plurality of core caches, each core cache associated with a single core, a plurality of low drop out (LDO) devices, each LDO device associated with a single core for scaling operating voltage to the core; and a memory for storing a lookup table that maps core operating frequency to core operating voltage and a voltage scaling algorithm for determining a core specific voltage scaling factor for each core. Each of the plurality of LDO devices applies the core specific voltage scaling factor determined by the algorithm. During operation, one core may operate at a different operating voltage than a second core for the same operating frequency.

### BRIEF DESCRIPTION OF THE DRAWINGS

FIG. 1 is a block diagram of an example multi-core processor having aspects for core specific voltage scaling.

FIG. 2 is a lookup table for default voltage settings and for core specific voltage scaling.

FIG. 3 is a block diagram of an example core and cache having a stored core specific voltage code.

FIG. 4 is a lookup table for default voltage settings and for core specific voltage scaling for each operating frequency.

FIG. 5 is a flow diagram of an example method for core specific voltage scaling.

FIG. 6 is a block diagram of an example multi-core processor with each core having a sensing unit for real time voltage scaling.

FIG. 7 is an example lookup table that includes a set of active core voltage scaling factors.

FIG. 8 is a flow diagram of an example method for core specific voltage scaling in real time.

FIG. 9 is a flow diagram of an example method for core specific voltage scaling.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Several aspects of a multi-core processor will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented with a “processing system” that includes one or more processors. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

Accordingly, in one or more exemplary embodiments, the functions described may be implemented in hardware, software, firmware, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise a random-access memory (RAM), a read-only memory (ROM), an electrically erasable programmable ROM (EEPROM), compact disk ROM (CD-ROM) or other optical disk storage, magnetic disk storage or other magnetic storage devices, or any other medium that can be used to carry or store desired program code in the form of instructions or data structures and that can be accessed by a computer. Combinations of the above should also be included within the scope of computer-readable media.

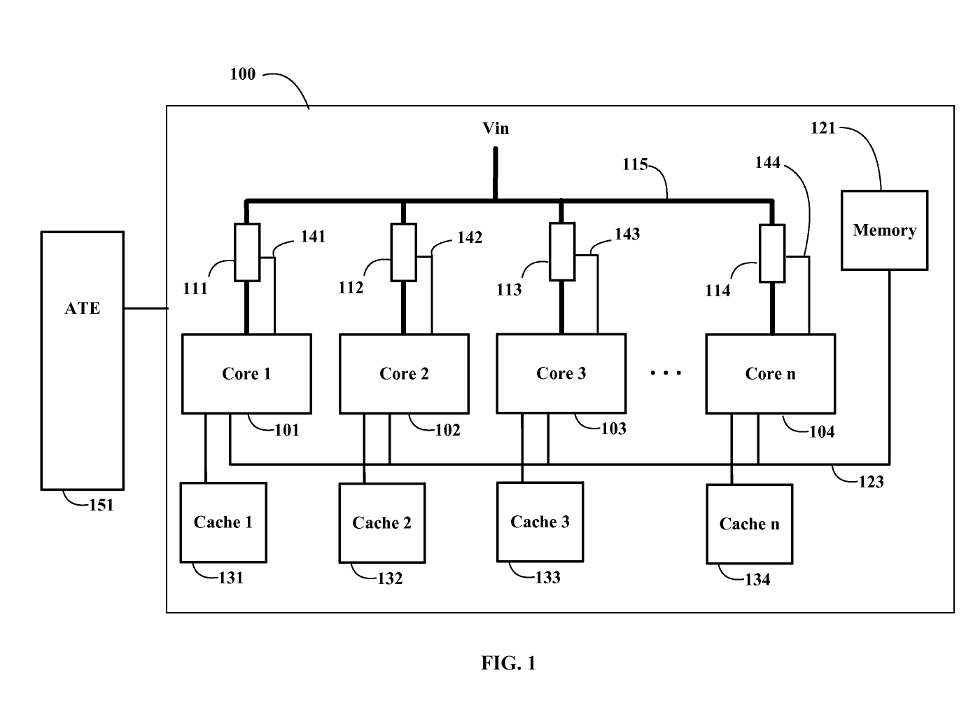

FIG. 1 is a block diagram illustrating an example multi-core processor 100 configured to determine a unique frequency/voltage performance of each core based on automatic test equipment feedback. A scaling factor may be assigned to each core and encoded in a core-specific cache. The processor 100 may include a plurality of cores, shown as cores 101-104. Input voltage Vi is a fixed value delivered to a common bus 115, which may be adjusted by low drop out (LDO) devices 111-114 respectively for individually scaling the voltage to each core 101-104. Each LDO 111-114 receives control instructions from control connections 141, 142, 143, 144 from the respective core 101, 102, 103, 104. Each core may execute software instructions stored in memory 121, and received on control bus 123 when any adjustment to the supply voltage is required. The memory 121 may be any form of computer readable medium as described above. Automatic test equipment (ATE) 151 may be connected to the processor 100 to determine the frequency/voltage relationship for each individual core 101-104 and establish an appropriate voltage factor for each core based on the results. Alternatively, the multi-processor 100 may use a self-testing module to perform the frequency/voltage relationship. Due to manufacturing variations, each core may operate faster or slower when compared to another core, (i.e., at a different frequency for a particular voltage). Hence, each core may require a different voltage to operate at a particular operating frequency. For example, at an operating frequency of 2GHz, core 101 may require 2.0V, core 102 may only require 1.8V, core 103 may require 1.4V and core 104 may require 1.6V. Accordingly, the voltage for cores 101-104 can be normalized according to a representative core, such as core 101 for example, with scaling factors assigned to each core as shown in Table 1. Such a voltage scaling factor, based on a test at a single representative operating frequency, may then be applied for adjusting the voltage at any operating frequency. This may, for example, be implemented using a lookup table stored in memory 121.

TABLE 1

| Core | Voltage scaling factor |
|---|---|
| 101 | 1.0 |
| 102 | 0.9 |
| 103 | 0.7 |
| 104 | 0.8 |

The ATE 151 may repeat the testing at several frequencies, and determine a set of voltage scaling factors for each core that is dependent upon frequency. Such a set of voltage scaling factors may be stored and implemented as a lookup table in memory 121. Alternatively, the ATE 151 may average the set of scaling factors to derive a single average scaling factor that may be applied at all operating frequencies for simplicity. Each core 101-104 has a corresponding cache 131-134, which may store a unique core voltage scaling code that can be mapped to the unique voltage scaling value. Having the cores and voltage scaling factors encoded may allow the processor during operation to determine which core is running an application for a required frequency and to scale the supply voltage according to the predetermined unique scaling factor.

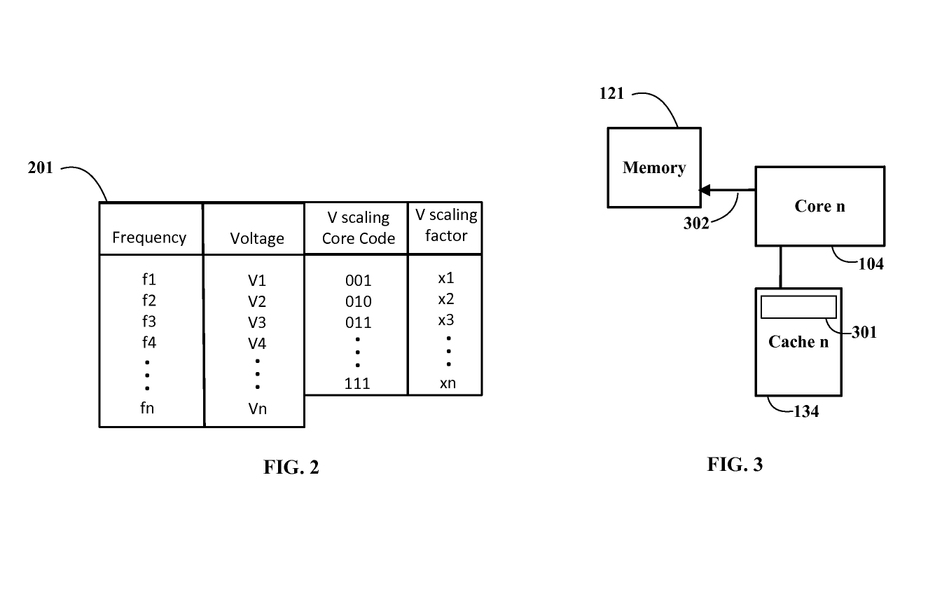

FIG. 2 shows an example frequency/voltage table 201 that may be stored in the memory 121 with encoded voltage scaling factors based the results of the scaling test of ATE 151. Frequencies f1, f2, f3, f4 . . . fn correspond to default voltages V1, V2, V3, V4 . . . Vn. According to an aspect consistent with the above description, each of the cores 101-104 is assigned voltage scaling core codes 001, 010, 011, 111. Each code is mapped to the unique scaling factor x1, x2, x3, xn, respectively. As an example, core 101 may be assigned core voltage code 001 which corresponds to a voltage scaling factor x1. If core 101 is running an application at an operating frequency f3, the default voltage V3 may be scaled by the voltage scaling factor x1.

FIG. 3 shows an example core 104 having the voltage scaling core code stored at address 301 in the cache 134. When the core 104 is running an application, it indicates the application and required operating frequency (e.g., f3) to memory 121, by sending a signal 302 on the control bus 123 with the frequency information, and the core voltage code 111. Based on a mapping in a lookup table, such as lookup table 201 stored in memory 121 for example, the corresponding default voltage V3 may be scaled by the voltage scaling factor xn, corresponding with core voltage code 111.

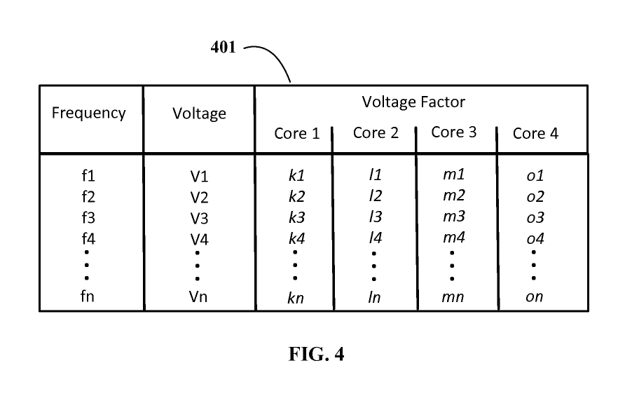

FIG. 4 shows an example lookup table 401 for an aspect in which a set of voltage scaling factors is determined by the ATE 151 for each core. The set of voltage scaling factors have a one-to-one mapping for each operating frequency f1 to fn. As shown, Core 1 has a set of voltage scaling factors k1 to kn, Core 2 has a set of scaling factors l1 to ln, Core 3 has a set of scaling factors m1 to mn, and Core 4 has a set of scaling factors of to on. As an example, when Core 3 is running at frequency f4, the corresponding default voltage V4 is scaled by voltage scaling factor m4.

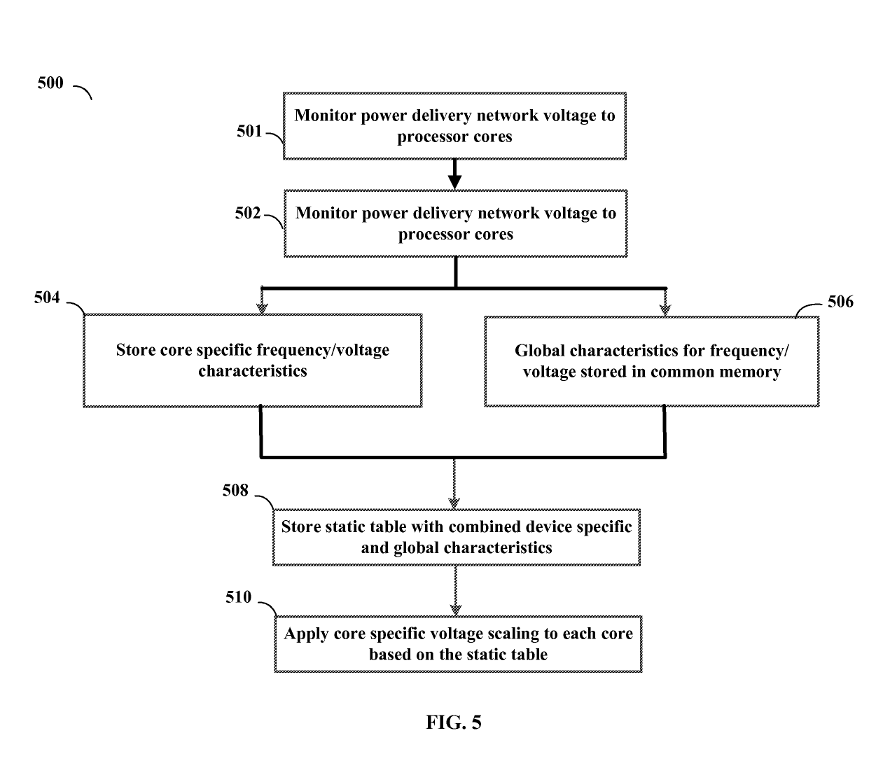

FIG. 5 shows a flow chart of an example method 500 for applying core specific voltage scaling. At 501, a power delivery network voltage to the processor cores is monitored. This may be performed by the ATE 151, for example, or alternatively by a self-test module in the multi-core processor 100. Based on the monitoring at one or more operating frequencies, a determination at 502 is made for how each core behaves uniquely with respect to the frequency/voltage relationship. This may be performed by the ATE 151, for example, or alternatively by a self-test module in the multi-core processor 100. Core specific frequency/voltage characteristics are stored at 504. For example, core specific frequency/voltage characteristics may be stored in a local cache of the core. Alternatively, the characteristics may be fused in the core as a hard encoding. For example, a core may have a unique voltage scaling identifier code fused in it. The global operating frequency/voltage characteristics may be stored in common memory, e.g., at 506. For example, the lookup table of default voltages for the corresponding operating frequencies may be stored in RAM of the multi-core processor 100. At 508, the core specific information may be combined with the lookup table of step 506 to form a static table that may be used during operation of the multi-core processor. At 510, each core has a core specific voltage scaling factor applied during operation based on the static table. The appropriate voltage scaling may be determined using the voltage scaling code associated with the core for mapping by the static table. The code may be sent by the core to a register in the memory and a voltage scaling algorithm in the memory may map the code to the voltage scaling factor in the static table.

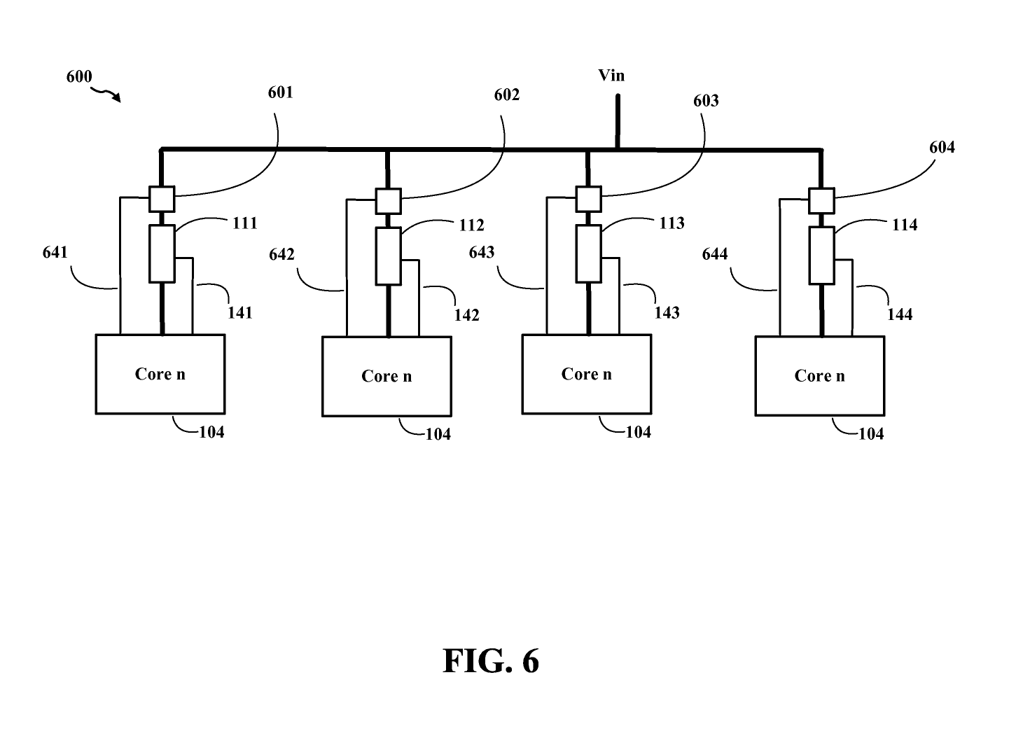

FIG. 6 shows a block diagram of a multi-core processor with each core having a sensing unit for determining real time voltage scaling. According to an aspect, each core 101, 102, 103, 104 may have a corresponding sensing unit 601, 602, 603, 604 that detects whether the number of active cores has changed. In response to such a detection, the sensing unit 601, 602, 603, 604 may send in indication on control line 641, 642, 643, 644 to the corresponding core that triggers additional voltage scaling in order to finely tune the voltage scaling applied according to the lookup table. A sensing unit may be implemented using a ring oscillator or a delay locked loop in which changes in delay indicate a change in operating frequency and change in the core input voltage. As an example, if at time t=0, all cores 101-104 are actively operating, then at time t=2, sensing unit 604 detects a change in input voltage parameters, from which it may determine that one or more cores 101-103 have become idle. The sensing unit 604 may further determine how many cores are active (or how many cores are idle). With reduced power losses through the power distribution to each core as each core is deactivated, the voltage requirements for the remaining active cores drops to some degree. A set of active core voltage scaling factors may be determined according to voltage distribution losses within the processor for each possible combination of active/idle cores. The set of active core voltage scaling factors may be stored in the frequency/voltage lookup table or a separate table to be used in conjunction with the frequency/voltage lookup table.

FIG. 7 shows an example lookup table 701 that includes a set of active core voltage scaling factors y1 . . . yn, which are based on the number of active cores. For example, if the sensing unit detects that three cores are active, then the scaling factor y3 is applied to the current input voltage setting in addition to the voltage scaling factor x1 . . . xn as described above. If all cores are active, then the active core voltage scaling factor is 1.0. If only one active core is detected, then the scaling factor y1 is applied, which provides the largest voltage reduction of the scaling factors y1 . . . yn.

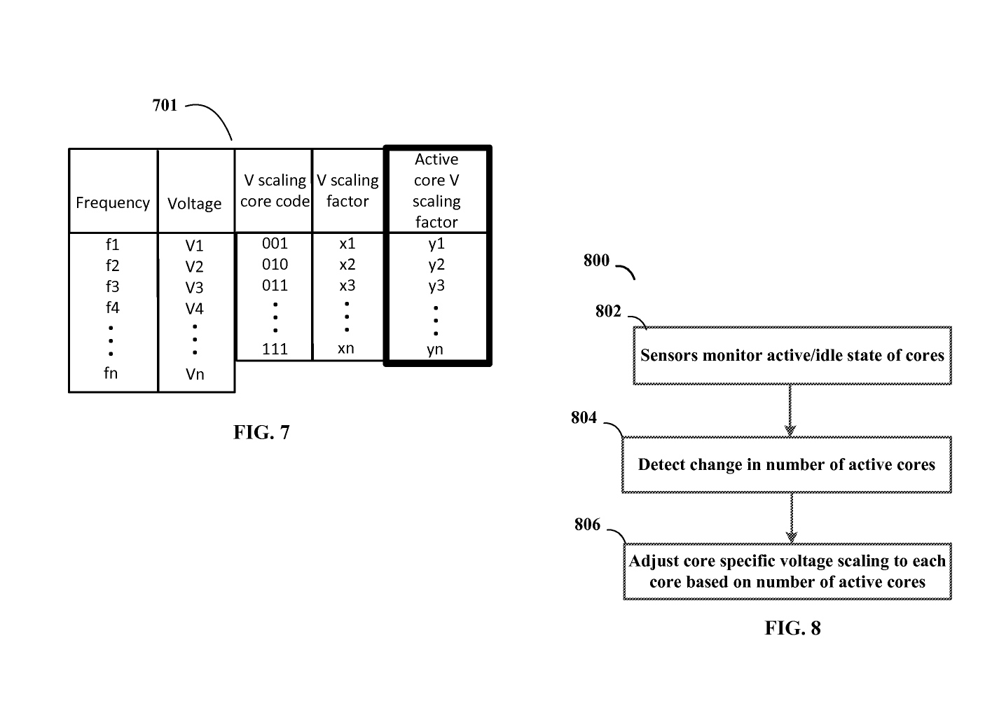

FIG. 8 shows a flow diagram of an example method 800 for core specific voltage scaling in real time. At 802, the sensing units monitor whether each of the cores are in active or idle state. At 804, the sensing units detect a change in the number of active cores, and trigger an indication for applying the active core voltage scaling factor. At 806, the core specific voltage scaling is adjusted based on the number of active cores. This detection and adjustment is performed continuously to provide real time voltage scaling in addition to the voltage scaling applied when the operating frequency is set for a currently running application on the core.

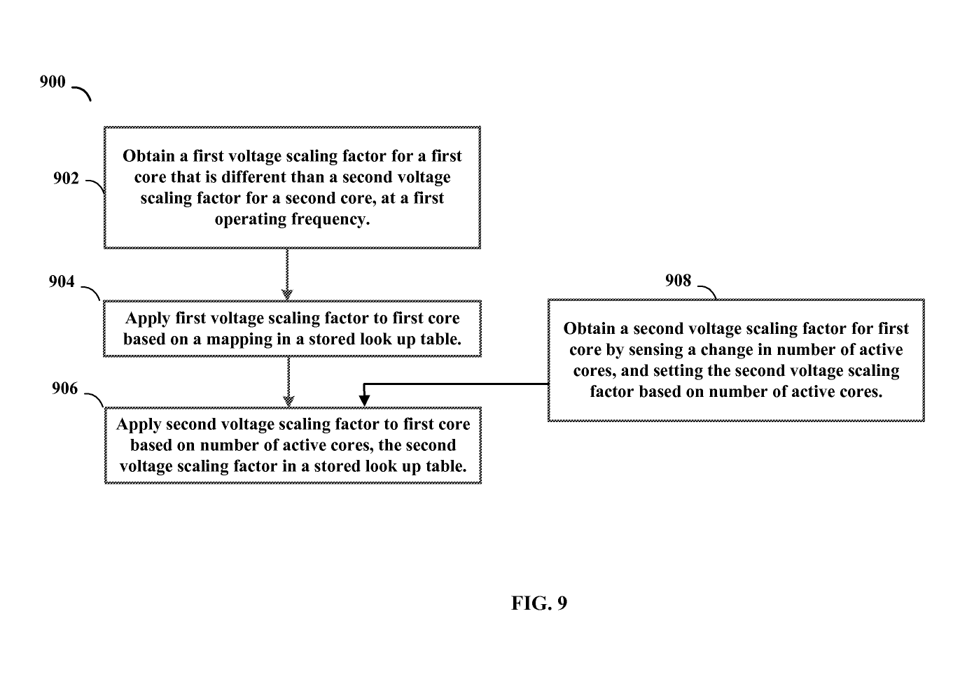

FIG. 9 shows a flow diagram of an example method 900 for core specific voltage scaling according to an aspect of the invention. At 902, a first core obtains a first voltage scaling factor for the first core in the multi-core processor to operate at a particular operating frequency. The first voltage scaling factor is different than a second voltage scaling factor for a second core to operate at the particular operating frequency. At 904, the voltage scaling factor may be applied to the first core based on a mapping stored in a look up table. The look up table may be stored locally at each core. The look up table may include a common table stored in a common memory in the multi-core processor. The look up table may include a voltage scaling factor for the first and second cores to operate at each of a plurality of operating frequencies. The look up table may include an average voltage scaling factor for the first core and an average voltage scaling factor for the second core. At 906, a second voltage scaling factor is applied to the first core, the second voltage scaling factor being obtained from a stored look up table. There may be a second voltage scaling factor for each possible combination of active and idle cores for the multi-core processor, where the second voltage scaling factor is based on a number of active cores. At 908, the second voltage scaling factor may be obtained by sensing a change in the number of active cores and setting the second voltage scaling based on the number of active cores.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A multi-core processor comprising;
a plurality of cores;
a plurality of core caches, each core cache associated with a single core; and
a plurality of low drop out (LDO) devices, each LDO device associated with a single core for scaling operating voltage to the core; and
a memory that comprises a lookup table that maps core operating frequency to core operating voltage, and a voltage scaling algorithm for determining a core specific voltage scaling factor for each core,
wherein each of the plurality of LDO devices applies the core specific voltage scaling factor determined by the algorithm;
wherein a first core operates at a first operating voltage different than an operating voltage of a second core.

2. The processor of claim 1, wherein each LDO device receives a control signal from the core for adjusting the operating voltage.

3. The processor of claim 1, wherein the lookup table further comprises a set of core specific voltage scaling factors.

4. The processor of claim 3, wherein the set of voltage scaling factors includes a one-to-one mapping to each operating frequency in the lookup table for each core.

5. The processor of claim 3, wherein the set of voltage scaling factors includes a single scaling factor for each core that is mapped to any operating frequency in the lookup table.

6. The processor of claim 3, wherein the each voltage scaling factor is based on an average of voltage scaling factors for different operating frequencies.

7. The processor of claim 3, wherein each core comprises a hard encoded core specific voltage scaling factor code.

8. The processor of claim 3, wherein each core cache comprises a stored core specific voltage scaling factor code.

9. The processor of claim 1, wherein the memory further comprises a core specific voltage scaling factor code stored in the lookup table.

10. The processor of claim 1, further comprising a plurality of sensing devices, each sensing device associated with a single core for detecting active/idle status of the single core.

11. The processor of claim 10, wherein each core determines the number of active cores and the lookup table further comprises a set of active core voltage scaling factors for a number of available active cores, wherein the voltage scaling algorithm determines an active core voltage scaling factor for applying to the scaling of operating voltage at each core.

12. The processor of claim 10, wherein each of the plurality of sensing devices comprises at least one of a ring oscillator or a delay locked loop.

13. A method for determining a core specific voltage scaling lookup table for a multi-core processor comprising:
monitoring a power delivery network voltage to a plurality of cores of the multi-processor at an operating frequency;
determining a mapping of operating frequency to operating voltage for each core; and
storing the mapping at the multi-core processor.

14. The method of claim 13, wherein the mapping is stored in a look up table.

15. The method of claim 13, wherein the mapping is stored locally at each core.

16. The method of claim 13, wherein a common mapping is stored at memory common to each of the cores.

17. The method of claim 13, further comprising:
encoding each core with a core specific voltage scaling code; and
storing the mapping including each core specific voltage scaling code.

18. The method of claim 13, wherein the monitoring is performed by an automatic test equipment.

19. The method of claim 13, wherein determining a mapping of operating frequency to operating voltage for each core includes determining a mapping for each possible combination of active and idle cores.

20. A method for applying a core specific voltage scaling factor to a multi-core processor, comprising:
obtaining a first voltage scaling factor for a first core in the multi-core processor to operate at a particular operating frequency, the first voltage scaling factor being different than a second voltage scaling factor for a second core to operate at the particular operating frequency; and
applying the voltage scaling factor to the first core.

21. The method of claim 20, wherein obtaining the first voltage scaling factor comprises using a look up table.

22. The method of claim 20, wherein the look up table is stored locally at each core.

23. The method of claim 20, wherein the look up table comprises a common table stored in a common memory in the multi-core processor.

24. The method of claim 20, wherein the look up table comprises a voltage scaling factor for the first and second cores to operate at each of a plurality of operating frequencies.

25. The method of claim 20, wherein the look up table comprises an average voltage scaling factor for the first core and an average voltage scaling factor for the second core.

26. The method of claim 20, wherein the look up table further comprises a second voltage scaling factor for each possible combination of active and idle cores for the multi-core processor, the method further comprising:
applying a second voltage scaling factor based on a number of active cores.

27. The method of claim 26, further comprising:
sensing a change in the number of active cores; and
setting the second voltage scaling factor based on the number of active cores.
